(19) United States
(12) Patent Application Publication
(10) Pub. No.: US 2019/0379360 A1
(43) Pub. Date: Dec. 12, 2019

(54) TRIGGER CIRCUIT

(71) Applicant: Realtek Semiconductor Corp., HsinChu (TW)

(72) Inventors: Hsin-Cheng Hsu, Hsinchu County (TW); Tay-Her Tsaur, Hsinchu County (TW); Po-Ching Lin, Hsinchu County (TW)

(21) Appl. No.: 16/248,807

(22) Filed: Jan. 16, 2019

(30) Foreign Application Priority Data
Jun. 11, 2018 (TW) 107120011

(51) Int. Cl. H03K 3/012; H03K 19/0948; H03K 5/24

(52) U.S. Cl. CPC H03K 3/012; H03K 5/24; H03K 19/0948

(57) ABSTRACT

A trigger circuit, including: an input terminal, an output terminal, a control circuit and a logic circuit. The control circuit is coupled to the input terminal and the output terminal. The control circuit receives an input voltage from the input terminal and an output voltage from the output terminal, and generates a plurality of reference voltages at least according to the input voltage and the output voltage. The logic circuit is coupled to the control circuit and the output terminal. When the input voltage is converted into a second voltage value from a first voltage value, the control circuit controls the logic circuit through the plurality of reference voltages to convert the output voltage into the first voltage value from the second voltage value.

### BACKGROUND OF THE INVENTION

### 1. Field of the Invention

The present invention is related to electronic circuits, and more particularly, to a trigger circuit having protection mechanism.

### 2. Description of the Prior Art

With the rapid development of Complementary Metal-Oxide-Semiconductor (CMOS) technology, sizes of transistors are significantly shrunk to reduce chip areas, and therefore operating speed increases and power consumption can be saved. However, as the sizes of the transistors are shrunk, gate oxides and transistor channels are shrunk as well, and the maximum allowable voltage difference between any two terminals of electrodes of any of the transistors (e.g. gate, drain, source and bulk/body) is reduced correspondingly. When a voltage difference between any two terminals of a transistor exceeds a nominal voltage, the transistor may be damaged. Since the nominal voltage of advanced CMOS process is getting lower, a conventional CMOS Schmitt trigger circuit may have problems such as damage due to a power source voltage higher than the nominal voltage.

### SUMMARY OF THE INVENTION

An objective of the present invention is to provide a trigger circuit to solve the aforementioned problems.

According to an embodiment of the present invention, a trigger circuit is disclosed. The trigger circuit comprises an input terminal, an output terminal, a control circuit and a logic circuit. The control circuit is coupled to the input terminal and the output terminal. The control circuit receives an input voltage from the input terminal and an output voltage from the output terminal, and the control circuit generates a plurality of reference voltages at least according to the input voltage and the output voltage. The logic circuit is coupled to the control circuit and the output terminal. When the input voltage is converted into a second voltage value from a first voltage value, the control circuit controls the logic circuit through the plurality of reference voltages to convert the output voltage into the first voltage value from the second voltage value.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a trigger circuit according to an embodiment of the present invention.

FIG. 2 is a diagram illustrating a logic circuit according to an embodiment of the present invention.

FIG. 3 is a diagram illustrating operations of the logic circuit according to a first embodiment of the present invention.

FIG. 4 is a diagram illustrating operations of the logic circuit according to a second embodiment of the present invention.

FIG. 5 is a diagram illustrating a control circuit according to an embodiment of the present invention.

FIG. 6 is a diagram illustrating comparator circuits within the control circuit according to an embodiment of the present invention.

### DETAILED DESCRIPTION

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should not be interpreted as a close-ended term such as “consist of”. Also, the term “couple” is intended to mean either an indirect or direct electrical connection. Accordingly, if one device is coupled to another device, that connection may be through a direct electrical connection, or through an indirect electrical connection via other devices and connections.

FIG. 1 is a diagram illustrating a trigger circuit 10 according to an embodiment of the present invention. As shown in FIG. 1, the trigger circuit 10 comprises an input terminal IN, an output terminal OUT, a control circuit 110 and a logic circuit 120. The control circuit 110 receives an input voltage Vin from the input terminal IN, and receives an output voltage Vout from the output terminal OUT, and generate reference voltages VSS, VDD, VDD×2, . . . and VDD×n according to the input voltage Vin and the output voltage Vout, where the reference voltage VSS (or the voltage value VSS thereof) may be a ground voltage. In other words, the reference voltage VSS may be the lowest voltage level within the trigger circuit 10, and the reference voltage VDD is the highest voltage level that can be applied to the trigger circuit 10 regarding the semiconductor process utilized for manufacturing the trigger circuit 10, that is, the nominal voltage. The reference voltages {VDD, VDD×2, . . . , VDD×n} have voltage values (e.g. voltage levels) VDD, VDD*2, . . . , and VDD*n, respectively, where the symbol n may be an integer greater than 2. In practice, the value of n is determined by practical applications, that is, the present invention is not limited to the value of n. The reference voltage VDD×n has the voltage value that is n times of the voltage value VDD of the reference voltage VDD, and the reference voltage VDD×n may be inputted from external part and outputted as a reference voltage of the logic circuit 120 through the control circuit 110.

In the present invention, when the input voltage Vin on the input terminal IN is converted into the reference voltage VDD×n (e.g. VDD*n) from the reference voltage VSS (e.g. VSS), the trigger circuit 10 may convert the output voltage Vout on the output terminal OUT into the reference voltage VSS (e.g. VSS) from the reference voltage VDD×n (e.g. VDD*n) through the control circuit 110 and the logic circuit 120. Similarly, when the input voltage Vin on the input terminal IN is converted into the reference voltage VSS (e.g. VSS) from the reference voltage VDD×n (e.g. VDD*n), the trigger circuit 10 may convert the output voltage Vout on the output terminal OUT into the reference voltage VDD×n (e.g. VDD*n) from the reference voltage VSS (e.g. VSS) through the control circuit 110 and the logic circuit 120. For better comprehension, when a reference voltage (e.g. any of the reference voltages VSS, VDD, VDD×2, . . . , VDD×n) is mentioned in the following, the voltage value thereof (e.g. the corresponding one of the voltage values VSS, VDD, VDD*2, . . . , and VDD*n) may be taken as an example of this reference voltage, but the present invention is not limited thereto. Further details of converting process will be described in subsequent paragraphs.

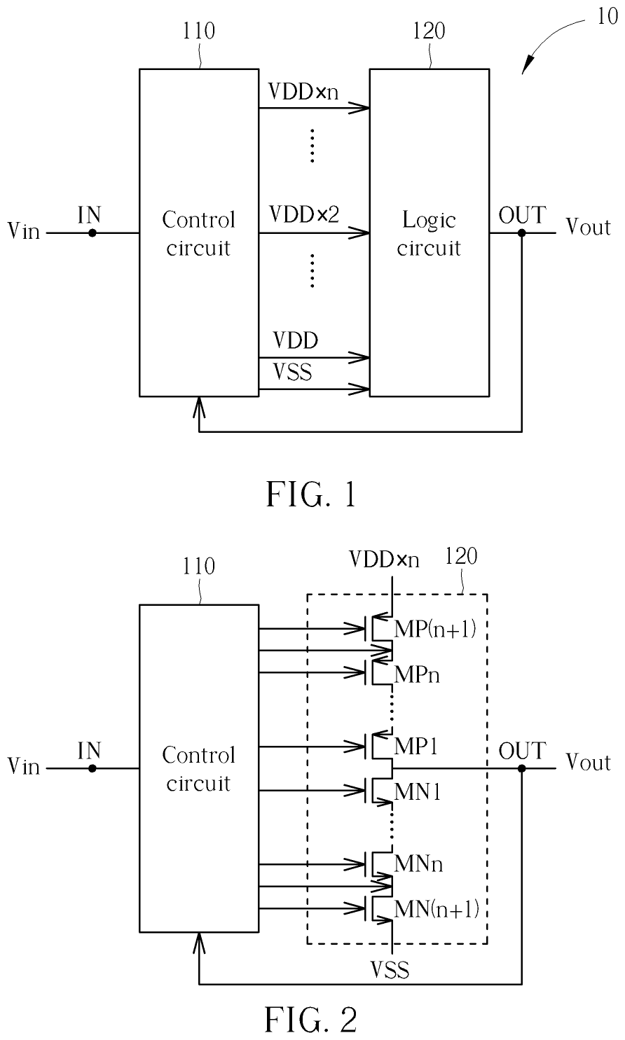

FIG. 2 is a diagram illustrating the logic circuit 120 according to an embodiment of the present invention. As shown in FIG. 2, the logic circuit 120 is a cascode structure formed by P-type Metal-Oxide-Semiconductor Field-Effect Transistors (MOSFETs) (which may be referred to as PMOSFETs, for brevity) MP1, MP2, . . . , MPn and MP(n+1) and N-type MOSFETs (which may be referred to as NMOSFETs, for brevity) MN1, MN2, . . . , MNn and MN(n+1). The symbol n here is the same as that in FIG. 1, and may represent a positive integer, for example, 3, 4, 5, and so on. The PMOSFETs and the NMOSFETs within the logic circuit 120 receive reference voltages from the control circuit 110 respectively through gate terminals of the PMOSFETs and the NMOSFETs, to control on/off states of MOSFETs (that is, the PMOSFETs and the NMOSFETs), and a source terminal of the PMOSFET MP (n+1) is coupled to the reference voltage VDD×n and a source terminal of the NMOSFET MN(n+1) is coupled to the reference voltage VSS. Please note that, the reference voltages VDD×n and VSS may be directly inputted from external part or generated through the control circuit 110. In addition, the control circuit 110 transmits reference voltages to a source terminal of the PMOSFET MPn and a source terminal of the NMOSFET MNn, and determines voltage values (e.g. voltage levels) of the reference voltages respectively received by the source terminal of the PMOSFET MPn and the source terminal of the NMOSFET MNn according to a voltage value of the output voltage Vout, to thereby control on/off states of the PMOSFET MPn and the NMOSFET MNn, and therefore complete conversion of the output voltage Vout.

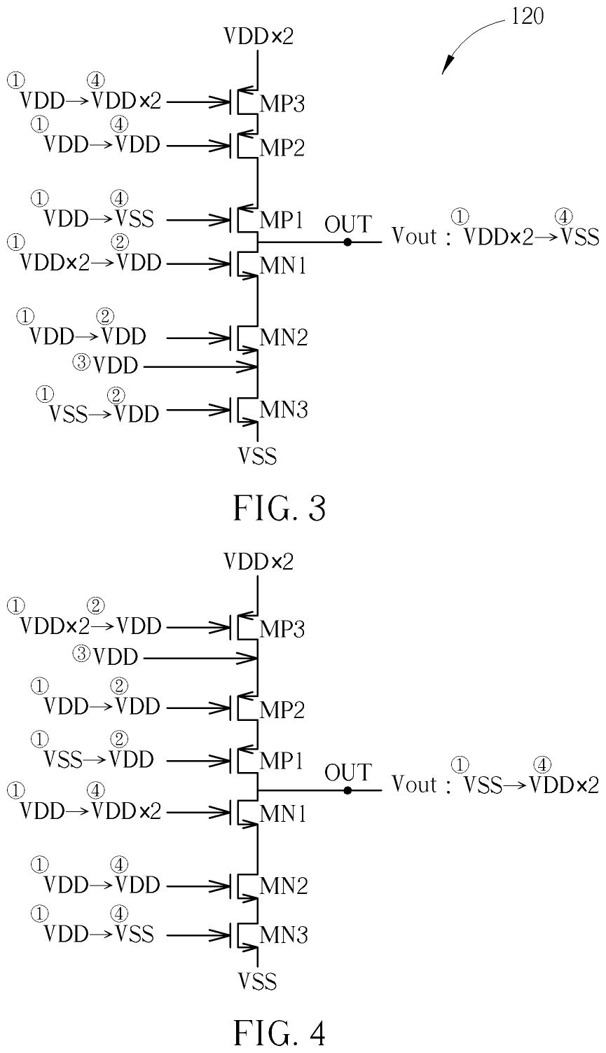

FIG. 3 is a diagram illustrating operations of the logic circuit 120 according to a first embodiment of the present invention, where n is 2 in this embodiment. In other words, the logic circuit 120 comprises PMOSFETs {MP1, MP2, MP3} and NMOSFETs {MN1, MN2, MN3}, forming a cascode structure as shown in FIG. 3. In this embodiment, the operations of the logic circuit 120 when the input voltage Vin is converted into the reference voltage VDD×2 from the reference voltage VSS is described. In an initial state (labeled a circle with a number “1” therein in FIG. 3 to indicate a first step), when the input voltage Vin is the reference voltage VSS, the output voltage Vout should be the reference voltage VDD×2 of the last conversion state. At this moment, gate terminals of the PMOSFETs MP1-MP3 receive the reference voltage VDD from the control circuit 110, and gate terminals of the NMOSFETs MN1-MN3 receive the reference voltages VDD×2, VDD and VSS, respectively. Next, the input voltage Vin increases, starting from the reference voltage VSS, the control circuit 110 transmits the reference voltage VDD to the gate terminals of the NMOSFETs MN1-MN3 (labeled a circle with a number “2” therein in FIG. 3 to indicate a second step), and those skilled in the art would easily understand that when an input voltage of a trigger circuit increases to a high voltage level from a low voltage level, the conversion may be performed only if the input voltage is higher than a high threshold voltage. Thus, when the input voltage increases, starting from the reference voltage VSS, but has not reached the high threshold voltage, the control circuit 110 further transmits the reference voltage VDD to a source terminal of the NMOSFET MN2 (labeled a circle with a number “3” therein in FIG. 3 to indicate a third step), to make both the gate terminal and the source terminal of the NMOSFET MN2 receive the reference voltage VDD and make the NMOSFET MN2 be turned off. Next, when the input voltage Vin is higher than the high threshold voltage, the control circuit 110 stop transmitting the reference voltage VDD to the source terminal of the NMOSFET MN2, and therefore the NMOSFET MN2 is turned on. At this moment, the NMOSFETs MN1-MN3 are all turned on, and transmit the reference voltage VSS to the output terminal OUT to make the output voltage Vout be converted into the reference voltage VSS from the reference voltage VDD×2 (labeled a circle with a number “4” therein in FIG. 3 to indicate a fourth step). Next, the control circuit 110 may simultaneously transmit a sequence of reference voltages, such as that starting from the reference voltage VSS and sequentially increasing with a common difference being the reference voltage VDD, to the PMOSFET MP1-MP3, respectively. In detail, the gate terminal of the PMOSFET MP1 receives the reference voltage VSS, the gate terminal of the PMOSFET MP2 receives the reference voltage VDD, and the gate terminal of the PMOSFET MP3 receives the reference voltage VDD×2, to make a sequence of gate voltages of these PMOSFETs MP1, MP2 and MP3 be an arithmetic sequence {VSS, VDD, VDD×2}. Because the gate voltage of the PMOSFET MP3 is VDD×2, the PMOSFET MP3 is turned off, and the rest of the PMOSFETs may have voltage-drop functions (or features) since the gate voltages of the PMOSFETs MP3, MP2 and MP1 are decreasing with the common difference being the reference voltage VDD. As a result, the output voltage Vout is successfully converted into the reference voltage VSS, and a voltage difference between any two terminals of any MOSFET within the logic circuit 120 will not exceed the nominal voltage, where the possibility of MOSFETs being damaged can be greatly reduced.

FIG. 4 is a diagram illustrating operations of the logic circuit 120 according to a second embodiment of the present invention. Similarly, n is 2 in this embodiment, and in other words, the logic circuit 120 comprises the PMOSFETs {MP1, MP2, MP3} and the NMOSFETs {MN1, MN2, MN3}, forming a cascode structure as shown in FIG. 4. In this embodiment, the operations of the logic circuit 120 when the input voltage Vin is converted into the reference voltage VSS from the reference voltage VDD×2 is described. In an initial state (labeled a circle with a number “1” therein in FIG. 4 to indicate a first step), when the input voltage Vin is the reference voltage VDD×2, the output voltage Vout should be the reference voltage VSS of the last conversion state. At this moment, the gate terminals of the NMOSFETs MN1-MN3 receive the reference voltage VDD from the control circuit 110, and the gate terminals of the PMOSFETs MP1-MP3 receive the reference voltages VSS, VDD and VDD×2, respectively. Next, the input voltage Vin decreases, starting from the reference voltage VDD×2, the control circuit 110 transmits reference voltage VDD to the gate terminals of the PMOSFETs MP1-MP3 (labeled a circle with a number “2” therein in FIG. 4 to indicate a second step), and as in the embodiment of FIG. 3, those skilled in the art would easily understand that when the input voltage of the trigger circuit decreases to the low voltage level from the high voltage level, the conversion may be performed only if the input voltage is lower than a low threshold voltage. Thus, when the input voltage decreases, starting from the reference voltage VDD×2, but has not reached the low threshold voltage, the control circuit 110 further transmits the reference voltage VDD to a source terminal of the PMOSFET MP2 (labeled a circle with a number “3” therein in FIG. 4 to indicate a third step), to make both the gate terminal and the source terminal of the PMOSFET MP2 receive the reference voltage VDD and make the PMOSFET MP2 be turned off. Next, when the input voltage Vin is lower than the low threshold voltage, the control circuit 110 stop transmitting the reference voltage VDD to the source terminal of the PMOSFET MP2, and therefore the PMOSFET MP2 is turned on. At this moment, the PMOSFETs MP1-MP3 are all turned on, and transmit the reference voltage VDD×2 to the output terminal OUT to make the output voltage Vout be converted into the reference voltage VDD×2 from the reference voltage VSS (labeled a circle with a number “4” therein in FIG. 4 to indicate a fourth step). Next, the control circuit 110 may simultaneously transmit a sequence of reference voltages, such as that starting from the reference voltage VDD×2 and sequentially decreasing with the common difference being the reference voltage VDD, to the NMOSFET MN1-MN3, respectively. In detail, the gate terminal of the NMOSFET MN1 receives the reference voltage VDD×2, the gate terminal of the NMOSFET MN2 receives the reference voltage VDD, and the gate terminal of the NMOSFET MN3 receives the reference voltage VSS, to make a sequence of gate voltages of these NMOSFETs MN1, MN2 and MN3 be an arithmetic sequence {VDD×2, VDD, VSS}. Because the gate voltage of the NMOSFET MN3 is VSS, the NMOSFET MN3 is turned off, and the rest of the NMOSFETs may have voltage-drop functions (or features) since the gate voltages of the NMOSFETs MN1, MN2 and MN3 are decreasing with the common difference being the reference voltage VDD. As a result, the output voltage Vout is successfully converted into the reference voltage VDD×2, and a voltage difference between any two terminals of any MOSFET within the logic circuit 120 will not exceed the nominal voltage, where the possibility of MOSFETs being damaged can be greatly reduced.

Please note that, in the embodiments of FIG. 3 and FIG. 4, a case that n=2 is taken as an example for descriptions, but the present invention is note limited thereto. When the value of the reference voltage VDD×n increases as the value of n increases (e.g. n=3, 4, 5, etc.), the number of MOSFETs forming a cascode structure within the logic circuit 120 may also increase, and thus, a voltage difference between any two terminals of any MOSFET within the logic circuit 120 will not exceed the nominal voltage in order to protect circuits. In addition, the present invention is not limited to the above implementation of the control circuit 110. In some embodiments, the control circuit may be implemented by hardware, for example, the control circuit 110 may be a processor. In other embodiments, the control circuit 110 may be implemented by software, firmware, and so on. As long as the control circuit 110 can generate the reference voltages VSS, VDD, . . . , VDD×(n−1) and VDD×n having the voltage values VSS, VDD, VDD*2, . . . , VDD*(n−1) and VDD*n, respectively, such implementation should belong to the scope of the present invention.

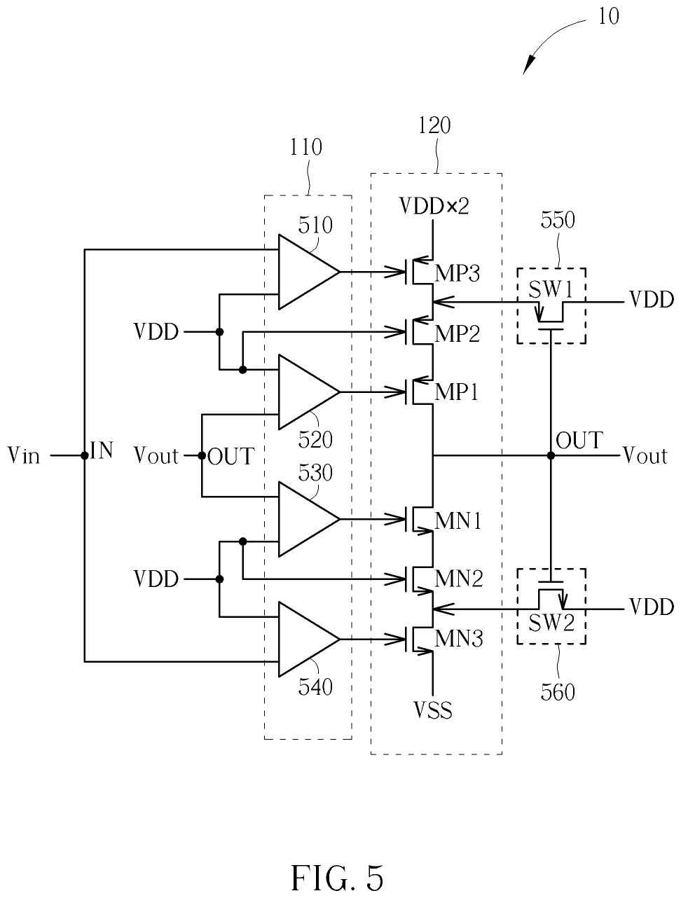

FIG. 5 is a diagram illustrating the control circuit 110 according to an embodiment of the present invention. As shown in FIG. 5, the control circuit 110 comprises comparator circuits 510, 520, 530 and 540 and switch circuits 550 and 560. For brevity and better comprehension, the switch circuits 550 and 560 and the comparator circuits 510, 520, 530 and 540 are illustrated separately in FIG. 5, but the switch circuits 550 and 560 and the comparator circuits 510, 520, 530 and 540 in this embodiment are all implemented in the same circuit. In this embodiment, the switch circuits 550 and 560 are implemented by a PMOSFET SW1 and an NMOSFET SW2, respectively. However, in other embodiments, the comparator circuits 510, 520, 530 and 540 and the switch circuits 550 and 560 may be individually implemented, respectively, and is not limited to be implemented in the same circuit. In detail, the comparator circuit 510 compares the input voltage Vin with the reference voltage VDD, and outputs the greater one within these two signals (or voltages) to the gate terminal of the PMOSFET MP3. The comparator circuit 520 compares the output voltage Vout with the reference voltage VDD, and outputs the lower one within these two signals (or voltages) to the gate terminal of the PMOSFET MP1. The comparator circuit 530 compares the output voltage Vout with the reference voltage VDD, and outputs the greater one within these two signals (or voltages) to the gate terminal of the NMOSFET MN1. The comparator circuit 540 compares the input voltage Vin with the reference voltage VDD, and outputs the lower one within these two signals (or voltages) to the gate terminal of the NMOSFET MN3. The control circuit 110 couples or transmits the reference voltage VDD to the gate terminals of the PMOSFET MP2 and the NMOSFET MN2. In addition, according to a voltage value of the output voltage Vout, the switch circuits 550 and 560 determine whether to make the PMOSFET SW1 and the NMOSFET SW2 conductive. When the PMOSFET SW1 and the NMOSFET SW2 are conductive, the switch circuits 550 and 560 (e.g. the PMOSFET SW1 and the NMOSFET SW2) transmit the reference voltage VDD to the source terminals of the PMOSFET MP2 and the NMOSFET MN2, respectively.

Referring to FIG. 3 and FIG. 5 together, in the initial state, the input voltage is the reference voltage VSS, and the output voltage Vout is the reference voltage VDD×2. Thus, according to features of the comparator circuits 510 and 520, the gate terminals of the PMOSFET MP1-MP3 all receive the reference voltage VDD from the control circuit 110, and according to features of the comparator circuits 530 and 540, the gate terminals of the NMOSFET MN1-MN3 receive the reference voltages VDD×2, VDD and VSS from the control circuit 110, respectively. In addition, the switch circuit 560 is conductive as the output voltage is VDD×2, and therefore transmits the reference voltage VDD to the source terminal of the NMOSFET MN2, and the NMOSFET MN2 is turned off as both the gate terminal and the source terminal thereof are the reference voltage VDD. After the input voltage Vin increases to the reference voltage VDD×2 from the reference voltage VSS, the gate terminals of the PMOSFETs MP2 and MP3 receive the reference voltages VDD and VDD×2 from the control circuit 110, respectively, and the gate terminal of the NMOSFET MN3 receives the reference voltage VDD from the control circuit 110. At this moment, the output voltage Vout is gradually decreasing, and finally turns off the switch circuit 560. Thus, all of the NMOSFETs MN1-MN3 are conductive, to thereby convert the output voltage Vout into the reference voltage VSS to complete the conversion, and the gate terminals of the NMOSFETs MN1 and MN2 receive the reference voltage VDD and the gate terminal of the PMOSFET MP1 receives the reference voltage VSS, to thereby implement the embodiment of FIG. 3.

Referring to FIG. 4 and FIG. 5 together, in the initial state, the input voltage is the reference voltage VDD×2, and the output voltage Vout is the reference voltage VSS. Thus, according to the features of the comparator circuits 510 and 520, the gate terminals of the PMOSFET MP1-MP3 receive the reference voltages VSS, VDD and VDD×2 from the control circuit 110, respectively, and according to the features of the comparator circuits 530 and 540, the gate terminals of the NMOSFET MN1-MN3 all receive the reference voltage VDD from the control circuit 110. In addition, the switch circuit 550 is conductive as the output voltage is VSS, and therefore transmits the reference voltage VDD to the source terminal of the PMOSFET MP2, and the PMOSFET MP2 is turned off as both the gate terminal and the source terminal thereof are the reference voltage VDD. After the input voltage Vin decreases to the reference voltage VSS from the reference voltage VDD×2, the gate terminals of the PMOSFETs MP2 and MP3 receive the reference voltages VDD from the control circuit 110, and the gate terminal of the NMOSFET MN3 receives the reference voltage VSS from the control circuit 110. At this moment, the output voltage Vout is gradually increasing, and finally turns off the switch circuit 550. Thus, all of the PMOSFETs MP1-MP3 are conductive, to thereby convert the output voltage Vout into the reference voltage VDD×2 to complete the conversion, and the gate terminals of the NMOSFETs MN1 and MN2 receive the reference voltage VDD×2 and VDD, respectively, and the gate terminal of the PMOSFET MP1 receives the reference voltage VDD, to thereby implement the embodiment of FIG. 4.

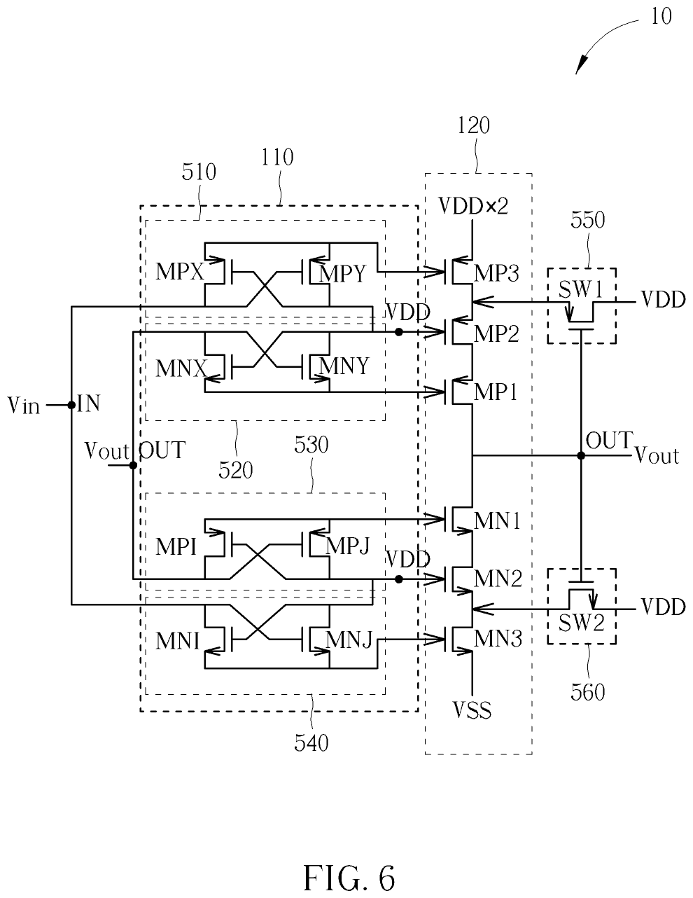

FIG. 6 is a diagram illustrating the comparator circuits 510-540 within the control circuit 110 according to an embodiment of the present invention. As shown in FIG. 6, each of the comparator circuits 510-540 is implemented by two MOSFETs. In detail, the comparator circuit 510 comprises PMOSFET MPX and MPY, where a gate terminal of the PMOSFET MPX is coupled to the reference voltage VDD and a gate terminal of the PMOSFET MPY is coupled to the input voltage Vin, and both source terminals of the PMOSFET MPX and MPY are coupled to the gate terminal of the PMOSFET MP3, to thereby output the greater one within the input voltage Vin and the reference voltage VDD to the gate terminal of the PMOSFET MP3. The comparator circuit 520 comprises NMOSFET MNX and MNY, where a gate terminal of the NMOSFET MNX is coupled to the reference voltage VDD and a gate terminal of the NMOSFET MNY is coupled to the output voltage Vout, and both source terminals of the NMOSFET MNX and MNY are coupled to the gate terminal of the PMOSFET MP1, to thereby output the lower one within the output voltage Vout and the reference voltage VDD to the gate terminal of the PMOSFET MP1. The comparator circuit 530 comprises PMOSFET MPI and MPJ, where a gate terminal of the PMOSFET MPI is coupled to the reference voltage VDD and a gate terminal of the PMOSFET MPJ is coupled to the output voltage Vout, and both source terminals of the PMOSFET MPI and MPJ are coupled to the gate terminal of the NMOSFET MN1, to thereby output the greater one within the output voltage Vout and the reference voltage VDD to the gate terminal of the NMOSFET MN1. The comparator circuit 540 comprises NMOSFET MNI and MNJ, where a gate terminal of the NMOSFET MNI is coupled to the reference voltage VDD and a gate terminal of the NMOSFET MNJ is coupled to the input voltage Vin, and both source terminals of the NMOSFET MNI and MNJ are coupled to the gate terminal of the NMOSFET MN3, to thereby output the lower one within the input voltage Vin and the reference voltage VDD to the gate terminal of the NMOSFET MN3.

Briefly summarized, the control circuit 110 transmits different reference voltages to the MOSFETs forming cascode structure within the logic circuit 120, to make sure that, after the conversion of an output voltage is completed, a voltage difference between any two terminals of any MOSFET within the logic circuit 120 will not exceed the nominal voltage. As a result, the risk of the MOSFETs being damaged can be greatly reduced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A trigger circuit, comprising:
an input terminal and an output terminal;
a control circuit, coupled to the input terminal and the output terminal, wherein the control circuit receives an input voltage from the input terminal and an output voltage from the output terminal, and generates a plurality of reference voltages at least according to the input voltage and the output voltage;
a logic circuit, coupled to the control circuit and the output terminal, wherein when the input voltage is converted into a second voltage value from a first voltage value, the control circuit controls the logic circuit through the plurality of reference voltages to convert the output voltage into the first voltage value from the second voltage value.

2. The trigger circuit of claim 1, wherein a sequence of voltage values of the plurality of reference voltages is an arithmetic sequence, and the first voltage value is one of a maximum voltage value and a minimum voltage value within the plurality of reference voltages, and the second voltage value is another one of the maximum voltage value and the minimum voltage value within the plurality of reference voltages.

3. The trigger circuit of claim 2, wherein the logic circuit comprises a plurality of Metal-Oxide-Semiconductor Field-Effect Transistors (MOSFETs).

4. The trigger circuit of claim 3, wherein when a variation amount of the input voltage is less than a default threshold, the control circuit transmits a specific reference voltage to a gate terminal and a source terminal of a specific MOSFET within the plurality of MOSFETs.

5. The trigger circuit of claim 4, wherein when the variation amount of the input voltage is greater than or equal to the default threshold, the control circuit stops transmitting the specific reference voltage to the source terminal of the specific MOSFET.

6. The trigger circuit of claim 4, wherein the first voltage value is less than the second voltage value, the specific MOSFET is an N-type MOSFET, and the plurality of MOSFETs comprises:
a plurality of P-type MOSFETs, wherein the plurality of P-type MOSFETs form cascode structure; and
a plurality of N-type MOSFETs, wherein the plurality of N-type MOSFETs form cascode structure;
wherein when the variation amount of the input voltage increasing from the first voltage value is less than the default threshold, the control circuit transmits the specific reference voltage to the gate terminal and the source terminal of the specific MOSFET.

7. The trigger circuit of claim 6, wherein when the variation amount of the input voltage increasing from the first voltage value is greater than or equal to the default threshold, a sequence of reference voltages transmitted to the plurality of P-type MOSFETs is an arithmetic sequence starting from the first voltage value, sequentially increasing with a common difference being the specific reference voltage, and ending at the second voltage value, and reference voltages transmitted to the plurality of N-type MOSFETs are the specific reference voltage.

8. The trigger circuit of claim 4, wherein the first voltage value is greater than the second voltage value, the specific MOSFET is a P-type MOSFET, and the plurality of MOSFETs comprises:
a plurality of P-type MOSFETs, wherein the plurality of P-type MOSFETs form cascode structure; and
a plurality of N-type MOSFETs, wherein the plurality of N-type MOSFETs form cascode structure;
wherein when the variation amount of the input voltage decreasing from the first voltage value is less than the default threshold, the control circuit transmits the specific reference voltage to the gate terminal and the source terminal of the specific MOSFET.

9. The trigger circuit of claim 8, wherein when the variation amount of the input voltage decreasing from the first voltage value is greater than or equal to the default threshold, reference voltages transmitted to the plurality of P-type MOSFETs are the specific reference voltage, and a sequence of reference voltages transmitted to the plurality of N-type MOSFETs is an arithmetic sequence starting from the first voltage value, sequentially decreasing with a common difference being the specific reference voltage, and ending at the second voltage value.

10. The trigger circuit of claim 1, wherein the control circuit comprises:
a comparator, arranged to compare the input voltage with a specific reference voltage, and output the greater one within the input voltage and the specific reference voltage to be one of the plurality of reference voltages.

11. The trigger circuit of claim 1, wherein the control circuit comprises:
a comparator, arranged to compare the output voltage with a specific reference voltage, and output the greater one within the output voltage and the specific reference voltage to be one of the plurality of reference voltages.

12. The trigger circuit of claim 1, wherein the control circuit comprises:
a comparator, arranged to compare the input voltage with a specific reference voltage, and output the lower one within the input voltage and the specific reference voltage to be one of the plurality of reference voltages.

13. The trigger circuit of claim 1, wherein the control circuit comprises:
a comparator, arranged to compare the output voltage with a specific reference voltage, and output the lower one within the output voltage and the specific reference voltage to be one of the plurality of reference voltages.

14. The trigger circuit of claim 1, wherein the logic circuit comprises a plurality of Metal-Oxide-Semiconductor Field-Effect Transistors (MOSFETs), and the control circuit comprises:
a switch circuit, arranged to determine whether to output a specific reference voltage to a source terminal of a specific MOSFET within the plurality of MOSFETs according to the output voltage.
